(19) United States
(12) Patent Application Publication
(10) Pub. No.: US 2015/0270190 A1
(43) Pub. Date: Sep. 24, 2015

(54) SEMICONDUCTOR PACKAGE

(71) Applicants: Jin-Gyu KIM, Asan-si (KR); Tae-Woo KANG, Suwon-si (KR); Tae-Hun KIM, Asan-si (KR)

(72) Inventors: Jin-Gyu KIM, Asan-si (KR); Tae-Woo KANG, Suwon-si (KR); Tae-Hun KIM, Asan-si (KR)

(21) Appl. No.: 14/497,441

(22) Filed: Sep. 26, 2014

(30) Foreign Application Priority Data
Mar. 18, 2014 (KR) 10-2014-0031766

(51) Int. Cl. H01L 23/367; H01L 23/373; H01L 23/31

(52) U.S. Cl. CPC H01L 23/3675; H01L 23/3107; H01L 23/3736

(57) ABSTRACT

A semiconductor package is provided. The semiconductor package includes a substrate, a semiconductor chip mounted on an upper surface of the substrate, an encapsulant formed to cover sides of the semiconductor chip on the upper surface of the substrate, a heat transfer layer formed on the upper surface of the semiconductor chip and an upper surface of the encapsulant, and a heat slug including a plurality of metal plates disposed to be spaced apart from each other on an upper surface of the heat transfer layer.

### CROSS-REFERENCE TO RELATED APPLICATION

This application claims priority under 35 U.S.C. §119 to Korean Patent Application No. 10-2014-0031766, filed on Mar. 18, 2014, the entire contents of which are incorporated herein by reference in their entirety.

### BACKGROUND

Embodiments relate to a semiconductor package. Various methods of reducing a thickness of a semiconductor package and effectively dissipating heat generated from a semiconductor chip are being studied. One method of improving heat dissipation characteristics of the semiconductor package is to use a heat slug. Methods of improving a bonding strength between the heat slug and the semiconductor package are being proposed.

### SUMMARY

Embodiments provide a semiconductor package. Other embodiments also provide a method of manufacturing the semiconductor package.

In accordance with an exemplary embodiment, a semiconductor package includes a substrate, a semiconductor chip mounted on an upper surface of the substrate, an encapsulant formed to cover sides of the semiconductor chip on the upper surface of the substrate, a heat transfer layer formed on an upper surface of the semiconductor chip and an upper surface of the encapsulant, and a heat slug including a plurality of metal plates disposed to be spaced apart from each other on an upper surface of the heat transfer layer.

In accordance with an exemplary embodiment, the heat slug may further include a connection layer formed between the plurality of metal plates.

In accordance with an exemplary embodiment, the connection layer may include a bonding material including a filler and a resin, or a thermal interface material (TIM).

In accordance with an exemplary embodiment, the plurality of metal plates may be coplanar with the connection layer.

In accordance with an exemplary embodiment, the connection layer may have a plurality of shapes parallel to each other in a plan view.

In accordance with an exemplary embodiment, the heat slug may include a capping film on the plurality of metal plates.

In accordance with an exemplary embodiment, the capping film may include one of a polyimide film and a metal film.

In accordance with an exemplary embodiment, the metal film may include one of copper (Cu), gold (Au), aluminum (Al), nickel (Ni), or an alloy thereof.

In accordance with an exemplary embodiment, an air space may exist between the heat transfer layer and the capping film.

In accordance with an exemplary embodiment, the heat transfer layer may extend between the plurality of metal plates.

In accordance with an exemplary embodiment, the heat transfer layer may include a thermal interface material (TIM) or a thermally conductive filler.

In accordance with an exemplary embodiment, the plurality of metal plates may include one of copper (Cu), gold (Au), aluminum (Al), nickel (Ni), or an alloy thereof.

In accordance with an exemplary embodiment, the encapsulant may cover the upper surface of the semiconductor chip.

In accordance with an exemplary embodiment, the plurality of metal plates may include a first metal plate located on the upper surface of the semiconductor chip and a second metal plate located on the encapsulant, and the first metal plate may have a greater horizontal width than the second metal plate.

In accordance with an exemplary embodiment, a semiconductor package includes a semiconductor chip mounted on a substrate, an encapsulant covering sides of the semiconductor chip, a plurality of metal plates disposed on the semiconductor chip and the encapsulant, and a connection layer disposed between the plurality of metal plates, wherein the plurality of metal plates include a first metal plate disposed on the semiconductor chip, and a second metal plate and a third metal plate disposed on the encapsulant to locate on both sides of the first metal plate.

In accordance with an exemplary embodiment, a heat transfer layer may be interposed between the plurality of metal plates and the semiconductor chip, and between a plurality of metal plates and the encapsulant. In accordance with an exemplary embodiment, the connection layer may include a bonding material including a filler and a resin, or a thermal interface material (TIM).

In accordance with an exemplary embodiment, the first metal plate may have substantially a greater thickness than the second and third metal plates.

In accordance with an exemplary embodiment, a semiconductor package includes a substrate, a semiconductor mounted on an upper surface of the substrate, an encapsulant formed to cover sides of the semiconductor chip on the upper surface of the substrate, a heat transfer layer formed on an upper surface of the semiconductor chip and an upper surface of the encapsulant, the heat slug on an upper heat transfer layer. The heat slug may include a plurality of metal plates disposed to be spaced apart from each other on the upper surface of the heat transfer layer, and a connection layer disposed between the plurality of metal plates.

In accordance with an exemplary embodiment, the heat slug may include a capping film on the plurality of metal plates.

### BRIEF DESCRIPTION OF THE DRAWINGS

The foregoing and other features and advantages will be apparent from the more particular description of preferred embodiments illustrated in the accompanying drawings, in which like reference characters refer to the same parts throughout the different views. The drawings are not necessarily to scale, emphasis instead being placed upon illustrating the principles of the embodiments. In the drawings:

FIGS. 1A-1C, 2A-2B, 3A-3B, 4-6, 7A-7C, 8, and 9A-9D illustrate schematic plan views and cross-sectional views of semiconductor packages according to various embodiments;

FIGS. 10A-10E, 11A-11C, and 12A-12D illustrate diagrams of methods of manufacturing semiconductor packages according to various embodiments; and

FIGS. 13 to 16 illustrate schematic diagrams of a module, electronic systems, and a mobile wireless phone to which the semiconductor packages according to various embodiments are applied.

### DETAILED DESCRIPTION OF THE EMBODIMENTS

Various embodiments will now be described more fully with reference to the accompanying drawings in which some embodiments are shown. These embodiments may, however, be embodied in different forms and should not be construed as limited to those set forth herein. Although a few embodiments have been shown and described, it would be appreciated by those of skill in the art that changes may be made in these exemplary embodiments without departing from the exemplary implementations.

The terminology used herein to describe embodiments is not intended to limit. The articles “a,” “an,” and “the” are singular in that they have a single referent, however the use of the singular form in the present document should not preclude the presence of more than one referent. In other words, elements referred to in the singular may number one or more, unless the context clearly indicates otherwise. It will be further understood that the terms “comprises,” “comprising,” “includes,” and/or “including,” when used herein, specify the presence of stated features, items, steps, operations, elements, and/or components, but do not preclude the presence or addition of one or more other features, items, steps, operations, elements, components, and/or groups thereof.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements. Other words used to describe relationships between elements should be interpreted in a like fashion (i.e., “between” versus “directly between,” “adjacent” versus “directly adjacent,” etc.). Herein, the term “and/or” includes any and all combinations of one or more referents.

Spatially relative terms (e.g., “beneath,” “below,” “lower,” “above,” “upper,” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations and/or plan illustrations that are schematic illustrations of idealized embodiments (and intermediate structures). In the drawings or figures, thicknesses of layers and regions may be exaggerated for effectively describing technical details. As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. Thus, the regions illustrated in the figures are schematic in nature and their shapes do not necessarily illustrate the actual shape of a region of a device and do not limit the scope.

Like reference numerals refer to like reference elements throughout. Accordingly, even though the like reference numerals or similar reference numerals are not referred to or explained in the corresponding drawings or figures, the like reference numerals or similar reference numerals may be explained with reference to other drawings or figures. Further, even though the reference numerals are not marked, the reference numerals may be explained with reference to other drawings or figures.

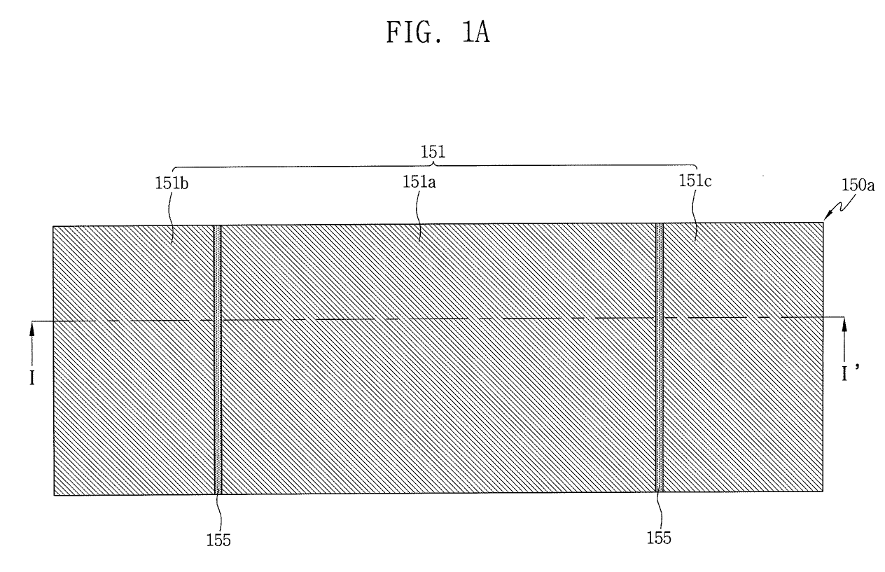

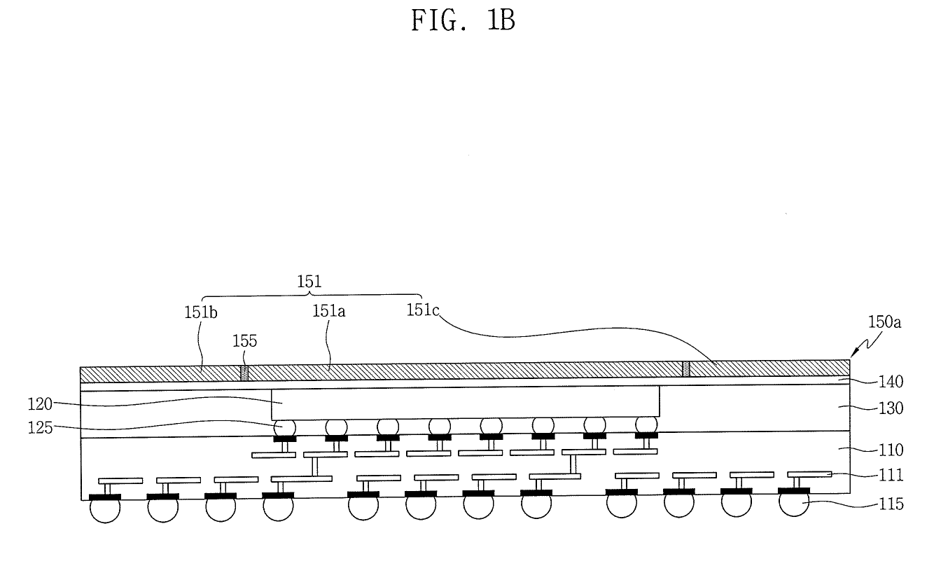

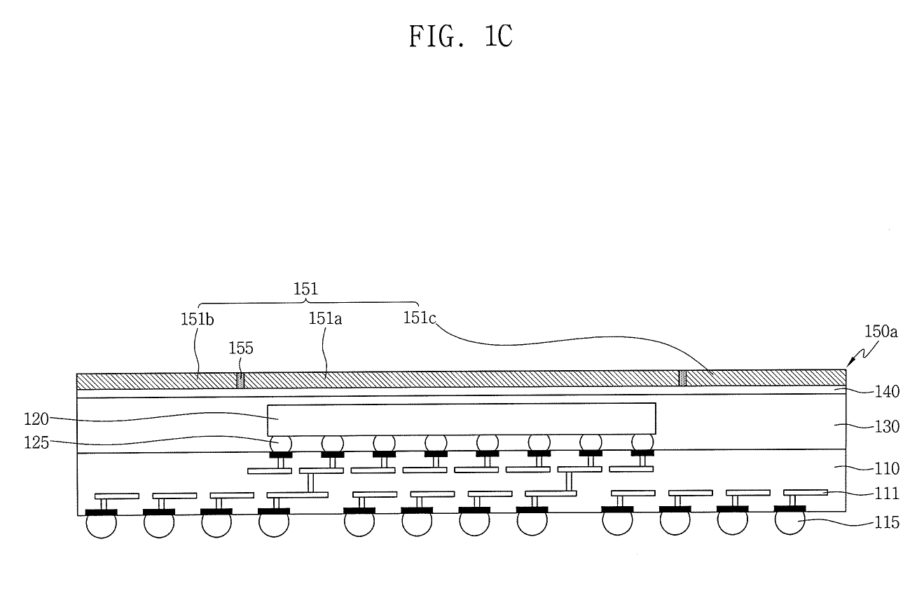

FIG. 1A is a schematic plan view illustrating a semiconductor package according to an exemplary embodiment, and FIGS. 1B and 1C are cross-sectional views taken along line I-I′ of FIG. 1A.

Referring to FIGS. 1A and 1B, the semiconductor package according to the embodiment may include a substrate 110, a semiconductor chip 120, an encapsulant 130, a heat transfer layer 140, and a heat slug 150a.

The substrate 110 may include one of a rigid printed circuit board, a flexible printed circuit board, or a rigid-flexible printed circuit board. The substrate 110 may include a single-layer printed circuit board or, a multi-layer printed circuit board. The substrate 110 may include a plurality of inner wires 111. A plurality of outer terminals 115 may be formed on a lower surface of the substrate 110. The plurality of outer terminals 115 may include one of a solder ball, a conductive bump, a pin grid array, a lead grid array, a copper pillar, or a combination thereof. The plurality of outer terminals 115 may be electrically connected to the plurality of inner wires 111.

The semiconductor chip 120 may include a logic chip. The semiconductor chip 120 may be mounted on an upper surface of the substrate 110. An upper surface of the semiconductor chip 120 may be exposed, and a lower surface of the semiconductor chip 120 may face the upper surface of the substrate 110. Inner terminals 125 may be formed between the upper surface of the substrate 110 and the lower surface of the semiconductor chip 120. The inner terminals 125 may include a solder ball or a copper pillar. The semiconductor chip 120 may be electrically connected to the outer terminals 115 through the inner terminals 125 and the inner wires 111. The semiconductor chip 120 may be mounted on the upper surface of the substrate 110 through the inner terminals 125 by a flip-chip bonding method.

The encapsulant 130 may be formed to cover sides of the semiconductor chip 120 on the substrate 110. The encapsulant 130 may include an epoxy molding compound (EMC). The upper surface of the semiconductor chip 120 and an upper surface of the encapsulant 130 may have a substantially coplanar plane. The encapsulant 130 may fill a space between the lower surface of the semiconductor chip 120 and the upper surface of the substrate 110. The inner terminals 125 may be electrically insulated from each other by the encapsulant 130.

The heat transfer layer 140 may be formed on the upper surfaces of the semiconductor chip 120 and the encapsulant 130. The heat transfer layer 140 may include a thermal interface material (TIM) having excellent heat transfer characteristics. The heat transfer layer 140 may formed by curing the liquid or paste TIM. The TIM may include one of a thermally conductive adhesive, a thermally conductive compound, a thermally conductive gel, or a prepreg. Further, the TIM may include a thermally conductive filler such as metal particles. The heat transfer layer 140 may be in contact with the upper surface of the semiconductor chip 120 and the heat slug 150a, and then effectively transfer heat generated from the semiconductor chip 120 to the heat slug 150a.

The heat slug 150a may be formed on an upper surface of the heat transfer layer 140. The heat slug 150a may emit the heat transferred through the heat transfer layer 140 to the outside. The heat slug 150a may include a plurality of metal plates 151 and a connection layer 155. For example, the plurality of metal plates 151 may include a first metal plate 151a located on the upper surface of the semiconductor chip 120, and a second metal plate 151b and a third metal plate 151c located on both sides of the first metal plate 151a and the upper surface of the encapsulant 130.

A horizontal width of the first metal plate 151a may be substantially equal to or greater than that of the upper surface of the semiconductor chip 120. The first, second, and third plates 151a, 151b, and 151c may be spaced apart from each other. The plurality of metal plates 151 may have different horizontal widths. For example, the first metal plate 151a located on the upper surface of the semiconductor chip 120 may have a greater horizontal width than the second and third metal plates 151b and 151c located on the encapsulant 130. In this case, the heat generated from the semiconductor chip 120 may be effectively emitted by increasing an area of the first metal plate 151a located on the upper surface of the semiconductor chip 120 where the heat is substantially generated.

The plurality of metal plates 151 may include one of copper (Cu), gold (Au), aluminum (Al), nickel (Ni), stainless steel, or an alloy thereof which has an excellent thermal conductivity. In another embodiment, the first metal plate 151a, and the second and third metal plates 151b and 151c may include different metals.

The connection layer 155 may be formed between the plurality of metal plates 151. The connection layer 155 may include a bonding material including a filler and a resin, and/or a TIM. The filler may include particles of nanometers or micrometers having thermal conductivity. The connection layer 155 may be formed by curing the bonding material including the filler and the resin, and/or the TIM. The metal plates 151 may be disposed parallel to each other. For example, the connection layer 155 formed between the metal plates 151 may have a line form, and the metal plates 151 and the connection layer 155 may be in parallel. For example, the connection layer 155 may have a plurality of straight line forms parallel to each other in the plan view.

Since the heat slug 150a according to an embodiment may include a plurality of metal plates 151 disposed to be spaced apart by a predetermined distance from each other, and a connection layer 155 connecting the plurality of metal plates 151, the plurality of metal plates 151 may be flexibly and independently movable. Since the plurality of metal plates 151 are flexibly movable in response to a direction of warpage generated in the semiconductor package due to a heat process among processes of manufacturing the semiconductor package, a bonding strength between the heat slug 150a and the heat transfer layer 140 may be increased.

Further, since the first metal plate 151a located on the upper surface of the semiconductor chip 120 among the plurality of metal plates 151 may have a greater horizontal width than the second and third metal plates 151b and 151c, an area of the first metal plate 151a located on a portion where the heat is substantially generated may be increased. Therefore, the heat slug 150a may flexibly respond to a direction of warpage of the semiconductor package and also efficiently emit the heat generated from the semiconductor chip 120.

Referring to FIGS. 1A and 1C, the semiconductor package according to an embodiment may include the substrate 110, the semiconductor chip 120, the encapsulant 130, the heat transfer layer 140, and the heat slug 150a. The encapsulant 130 may be formed to cover the upper surface of the semiconductor chip 120 on the upper surface of the substrate 110. The encapsulant 130 may include an EMC. The heat transfer layer 140 may be formed on the upper surface of the encapsulant 130.

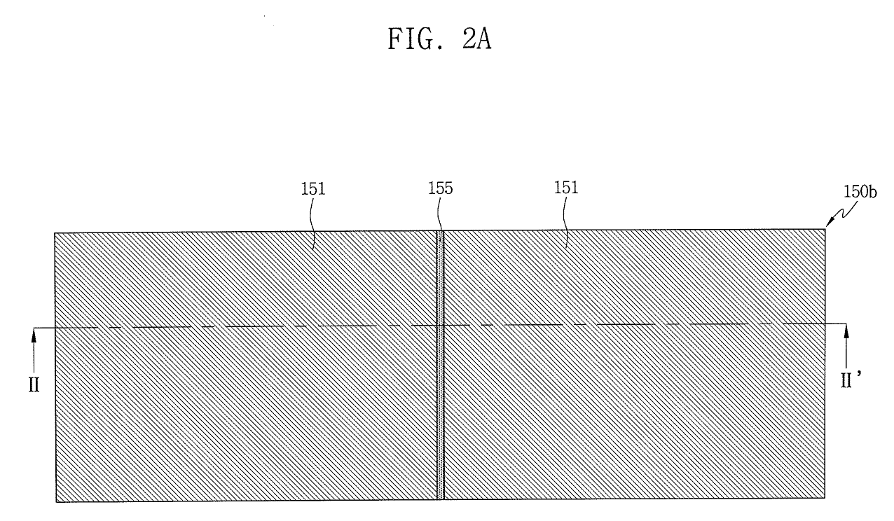

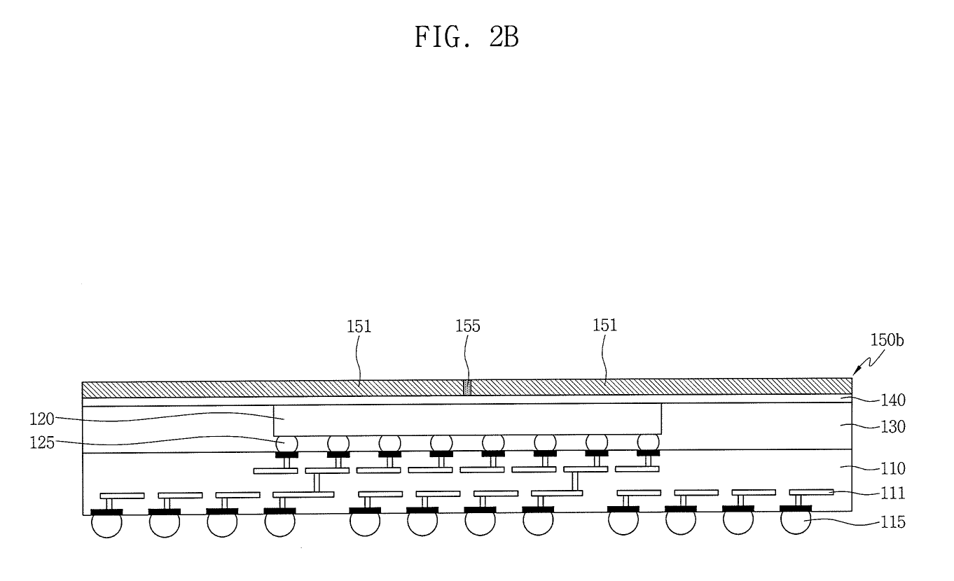

FIG. 2A is a schematic plan view illustrating a semiconductor package according to an exemplary embodiment, and FIG. 2B is cross-sectional view taken along line II-II′ of FIG. 2A.

Referring to FIGS. 2A and 2B, the semiconductor package according to the embodiment may include a substrate 110, a semiconductor chip 120, an encapsulant 130, a heat transfer layer 140, and a heat slug 150b. The heat slug 150b may include two metal plates 151, and a connection layer 155 formed between the two metal plates 151. A horizontal width of the two metal plates 151 may be substantially equal. In the embodiment, since the sizes of the two metal plates 151 are equal, it may be easy to manufacture the heat slug 150b. Further, the two separated metal plates 151 may flexibly respond to a direction of warpage generated in the semiconductor package. An area of the connection layer 155 may decrease, and areas of the two metal plates 151 may increase, and thus heat dissipation efficiency may be improved.

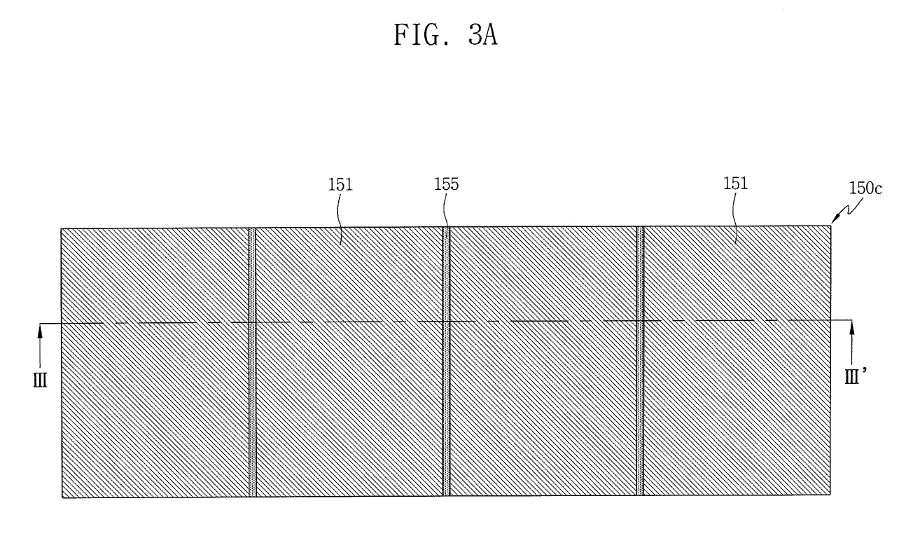

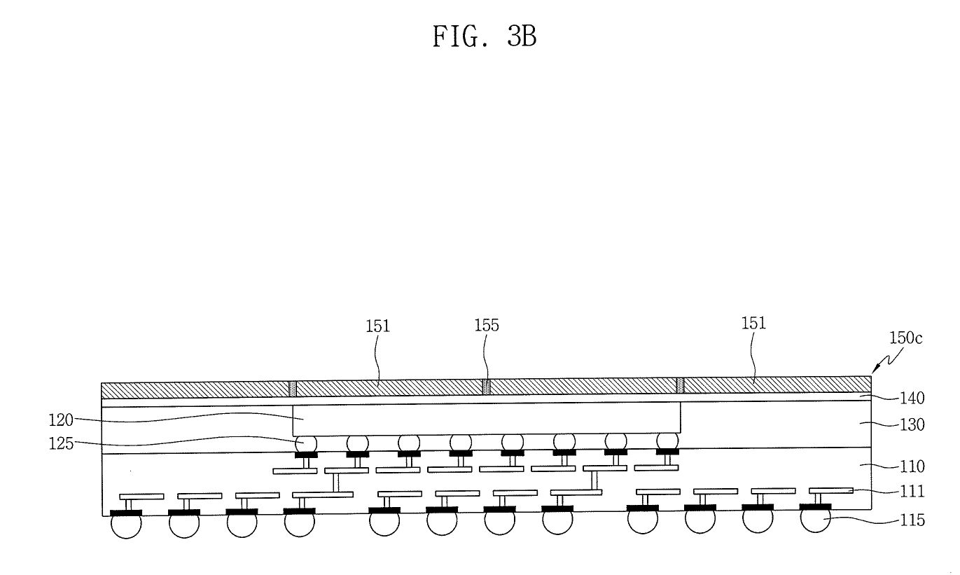

FIG. 3A is a schematic plan view illustrating a semiconductor package according to an exemplary embodiment, and FIG. 3B is cross-sectional view taken along line of FIG. 3A.

Referring to FIGS. 3A and 3B, the semiconductor package according to the embodiment may include a substrate 110, a semiconductor chip 120, an encapsulant 130, a heat transfer layer 140, and a heat slug 150c. The heat slug 150c may include a plurality of metal plates 151 separated and disposed in a horizontal direction, and a connection layer 155 formed between the plurality of metal plates 151. In this case, since the number of metal plates 151 is increased, the metal plates 151 may more flexibly respond to a direction of warpage generated in the semiconductor package.

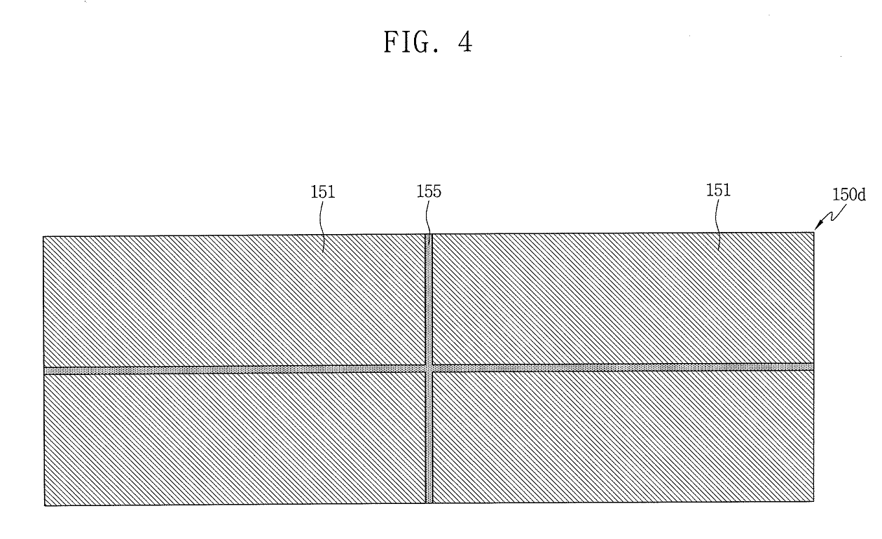

FIG. 4 is a schematic plan view illustrating a semiconductor package according to an exemplary embodiment. Referring to FIG. 4, a heat slug 150d may include a plurality of metal plates 151 separated and disposed in horizontal and vertical directions, and a connection layer 155 formed between the plurality of metal plates 151. Each of the plurality of metal plates 151 may have the same area.

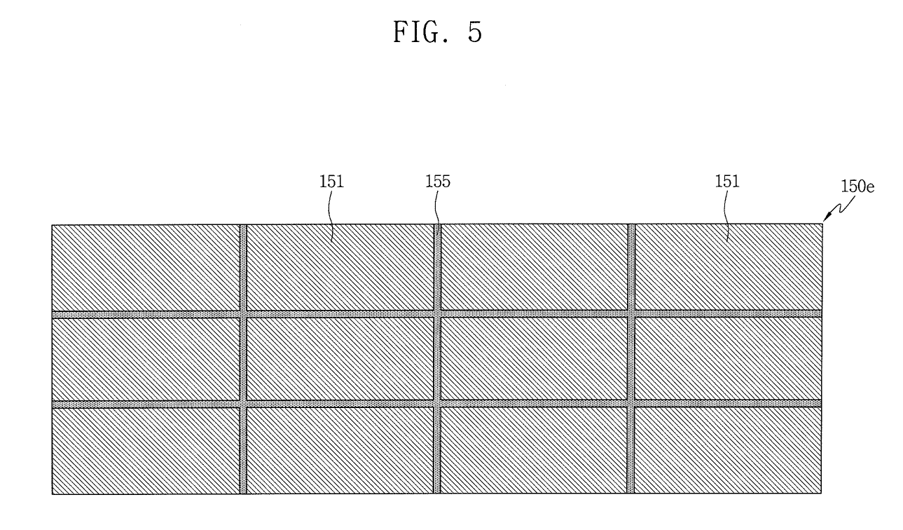

FIG. 5 is a schematic plan view illustrating a semiconductor package according to an exemplary embodiment. Referring to FIG. 5, a heat slug 150e may include a plurality of metal plates 151 separated and disposed in a grid form, and a connection layer 155 formed between the plurality of metal plates 151. Each of the plurality of metal plates 151 may have the same area.

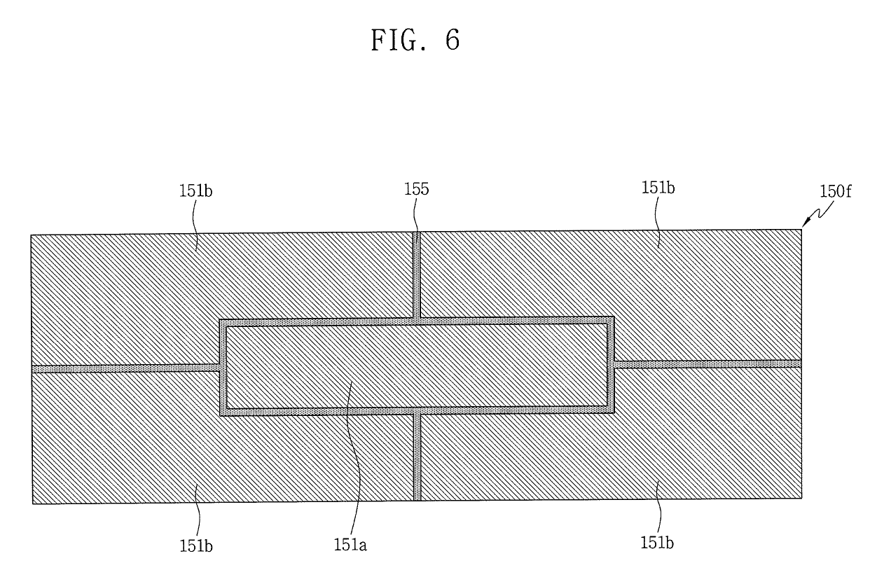

FIG. 6 is a schematic plan view illustrating a semiconductor package according to an exemplary embodiment. Referring to FIG. 6, a heat slug 150f may include a first metal plate 151a disposed in the center, second metal plates 151b disposed adjacent to the four corners of the first metal plate 151a, and a connection layer 155 formed between the first and second metal plates 151a and 151b. Each of the second metal plates 151b may have a folded shape corresponding to each of the four corners of the first metal plate 151a.

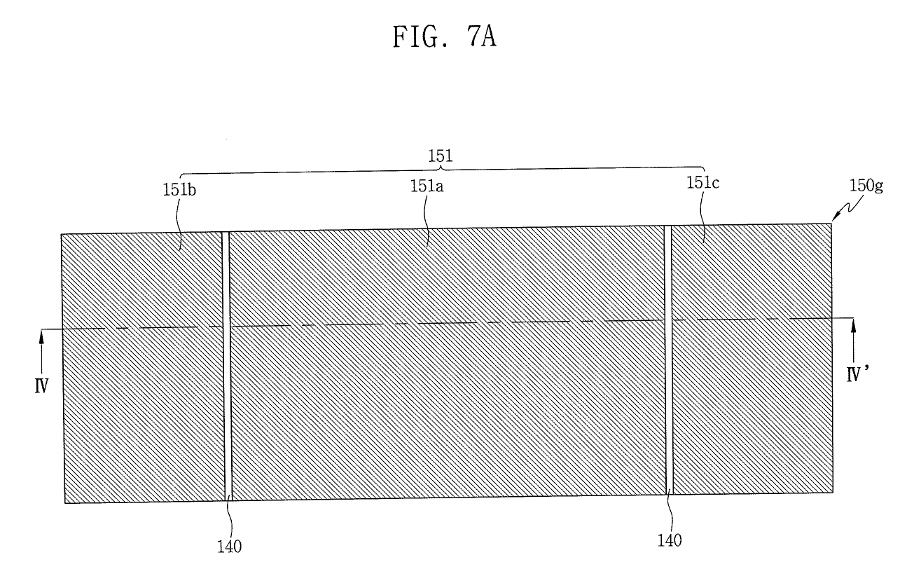

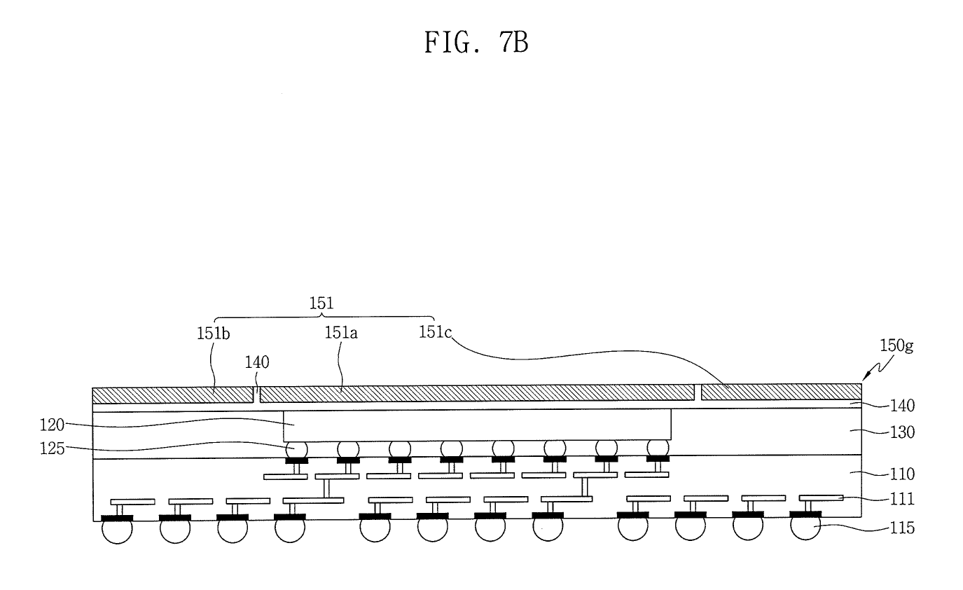

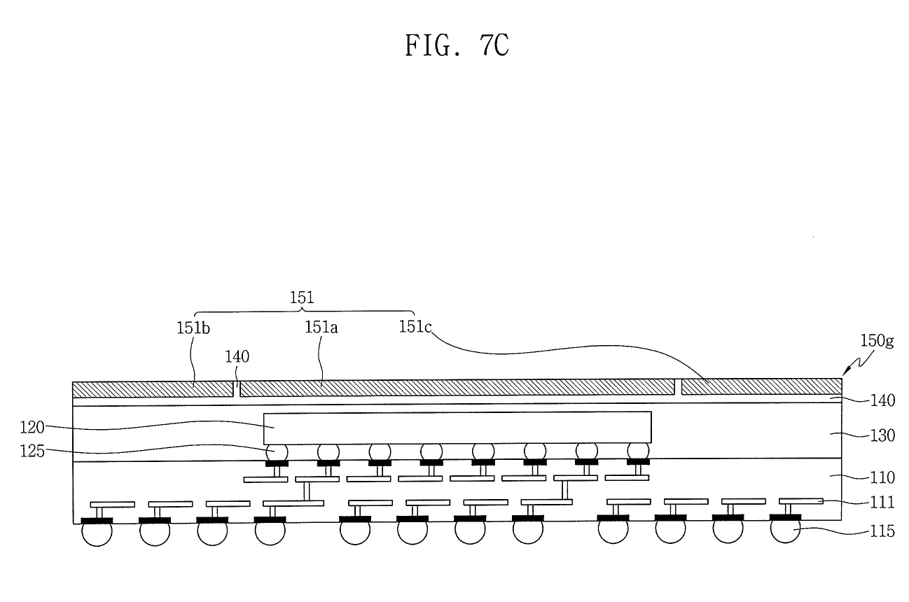

FIG. 7A is a schematic plan view illustrating a semiconductor packages according to an exemplary embodiment, and FIGS. 7B and 7C are cross-sectional views taken along line IV-IV of FIG. 7A.

Referring to FIGS. 7A and 7B, the semiconductor package according to the embodiment may include a substrate 110, a semiconductor chip 120, an encapsulant 130, a heat transfer layer 140, and a heat slug 150g. The heat slug 150g may include a plurality of metal plates 151 disposed to be spaced apart from each other. A heat transfer layer 140 may be interposed between the plurality of metal plates 151. For example, the heat transfer layer 140 may protrude between the plurality of metal plates 151 and fill between the plurality of metal plates 151. An upper surface of the heat transfer layer 140 and upper surfaces of the plurality of metal plates 151 may have a substantially coplanar plane.

Referring to FIG. 7C, the encapsulant 130 may cover an upper surface of the semiconductor chip 120.

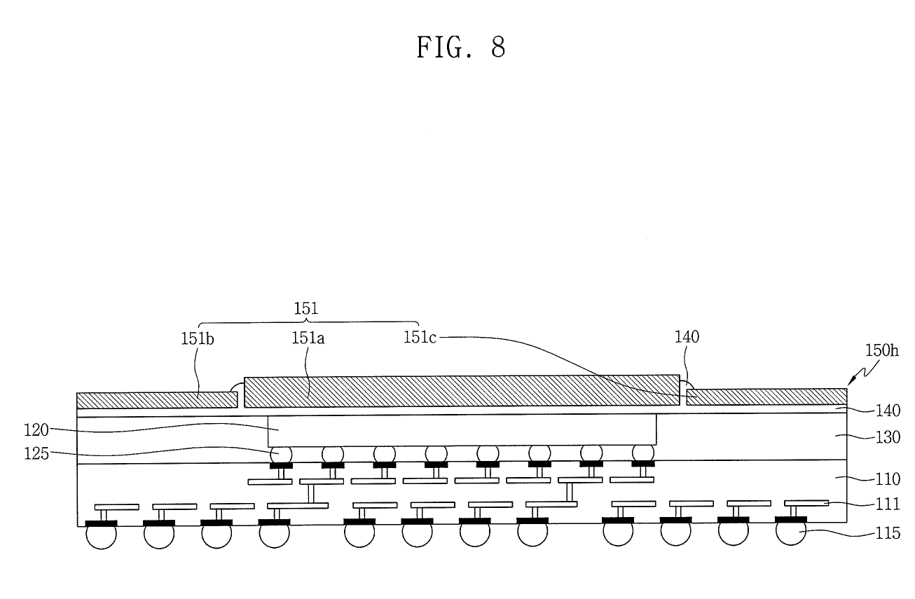

FIG. 8 is a cross-sectional view of a semiconductor package according to an exemplary embodiment. Referring to FIG. 8, the semiconductor package according to the embodiment may include a substrate 110, a semiconductor chip 120, an encapsulant 130, a heat transfer layer 140, and a heat slug 150h.

The heat slug 150h may include a plurality of metal plates 151 which have thicknesses different from each other. For example, the plurality of metal plates 151 may include a first metal plate 151a located on an upper surface of the semiconductor chip 120, second and third metal plates 151b and 151c located on sides of the first metal plate 151a and an upper surface of the encapsulant 130. The first metal plate 151a may have substantially a greater thickness than the second and third metal plates 151b and 151c. The heat transfer layer 140 may formed between the first metal plate 151a, and second and third metal plates 151b and 151c. In this case, an upper surface of the heat transfer layer 140 may be disposed at a lower level than an upper surface of the first metal plate 151a, and the heat transfer layer 140 cover portions of the upper surfaces of the second and third metal plates 151b and 151c. For example, the heat transfer layer 140 may be formed to cover portions of the upper surfaces of the second and third metal plates 151b and 151c adjacent to the first metal plate 151a. A horizontal width of the first metal plate 151a may be substantially equal to or greater than that of the semiconductor chip 120. The first metal plate 151a may have a greater horizontal width than the second and third metal plates 151b and 151c.

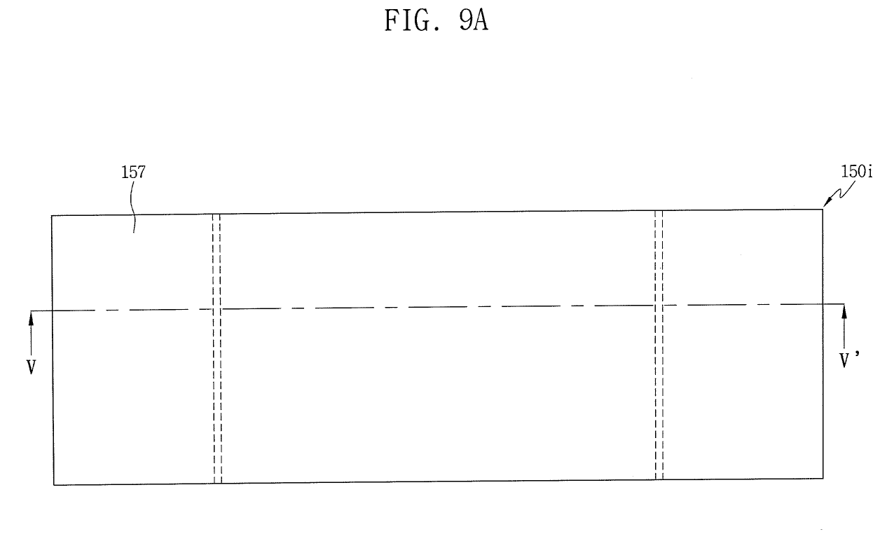

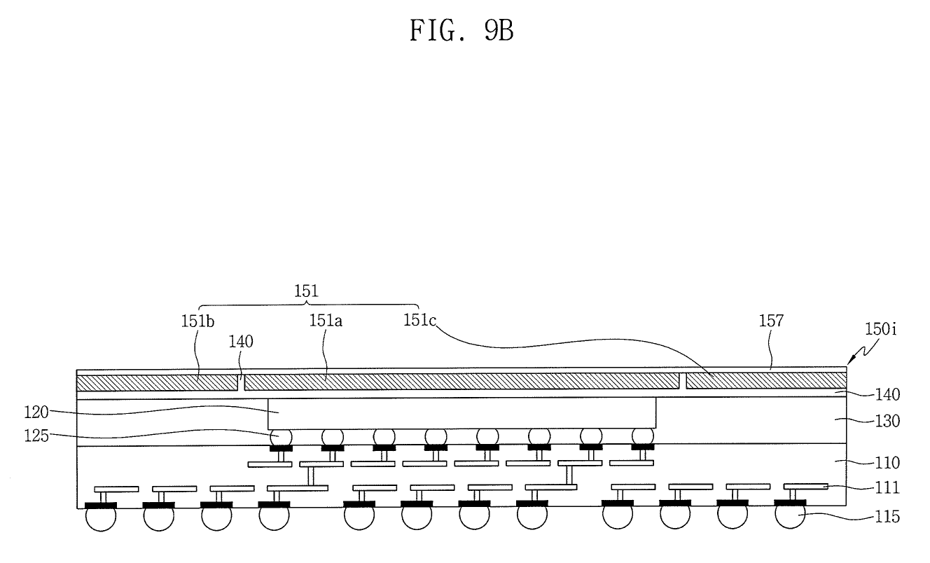

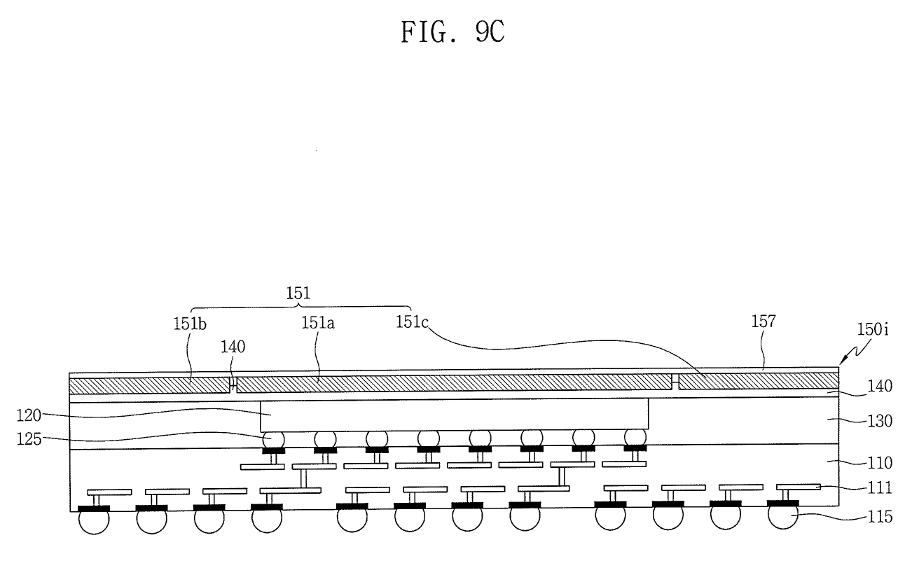

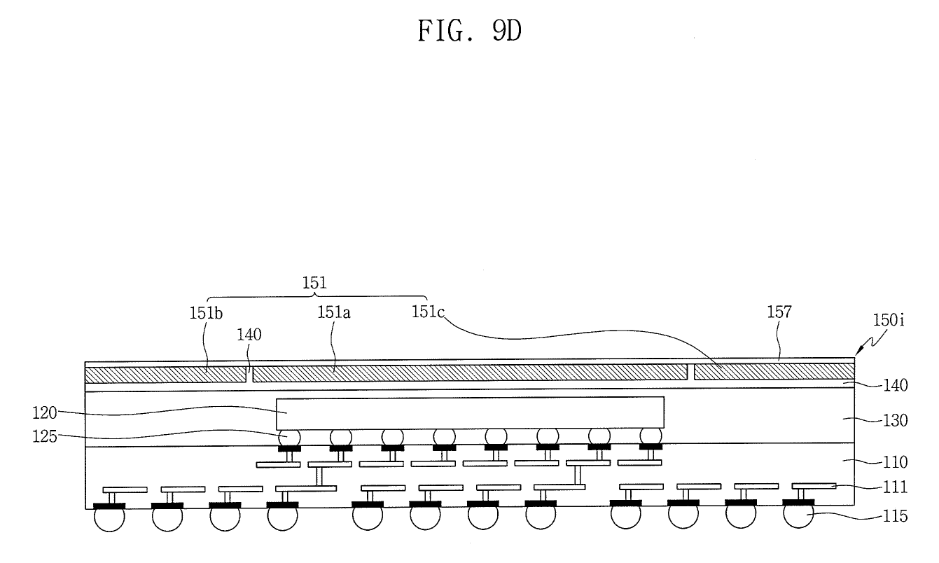

FIG. 9A is a schematic plan view illustrating a semiconductor package according to an exemplary embodiment, and FIGS. 9B to 9D are cross-sectional views taken along line V-V′ of FIG. 9A.

Referring to FIGS. 9A and 9B, the semiconductor package according to the embodiment may include a substrate 110, a semiconductor chip 120, an encapsulant 130, a heat transfer layer 140, and a heat slug 150i. The heat slug 150i may include a plurality of metal plates 151, and a capping film 157 formed on upper surfaces of the plurality of metal plates 151. The capping film 157 may include a polyimide film, or a metal film. The metal film may include one of copper (Cu), gold (Au), aluminum (Al), nickel (Ni), or an alloy thereof. The capping film 157 may be bonded to the plurality of metal plates 151, and provide physical stability preventing separation from the heat transfer layer 140.

The heat transfer layer 140 may be formed between the plurality of metal plates 151. An upper surface of the heat transfer layer 140 and the upper surfaces of the plurality of metal plates 151 may have a substantially coplanar plane.

Referring to FIG. 9C, the upper surface of the heat transfer layer 140 formed between the plurality of metal plates 151 may be formed at a lower level than the upper surfaces of the plurality of metal plates 151. There may be an air space between the heat transfer layer 140 and the capping film 157.

Referring to FIG. 9D, the encapsulant 130 may cover the upper surface of the semiconductor chip 120.

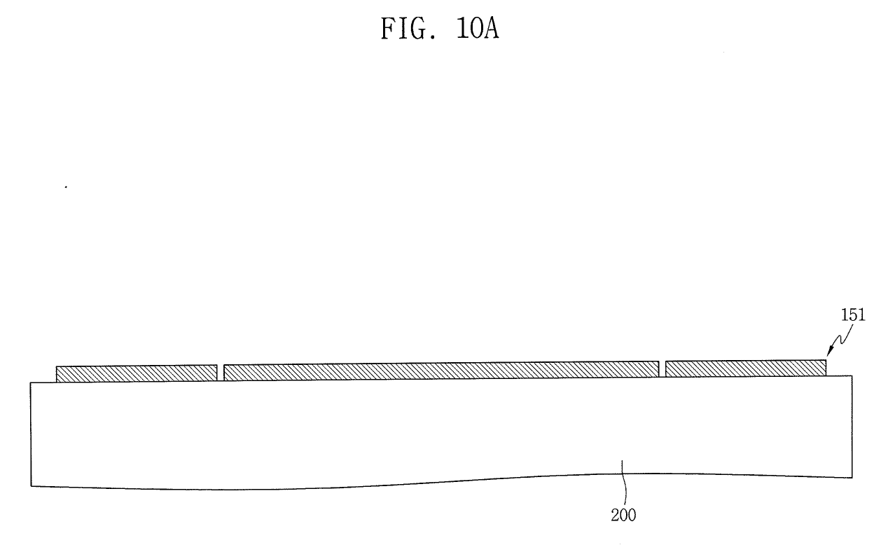

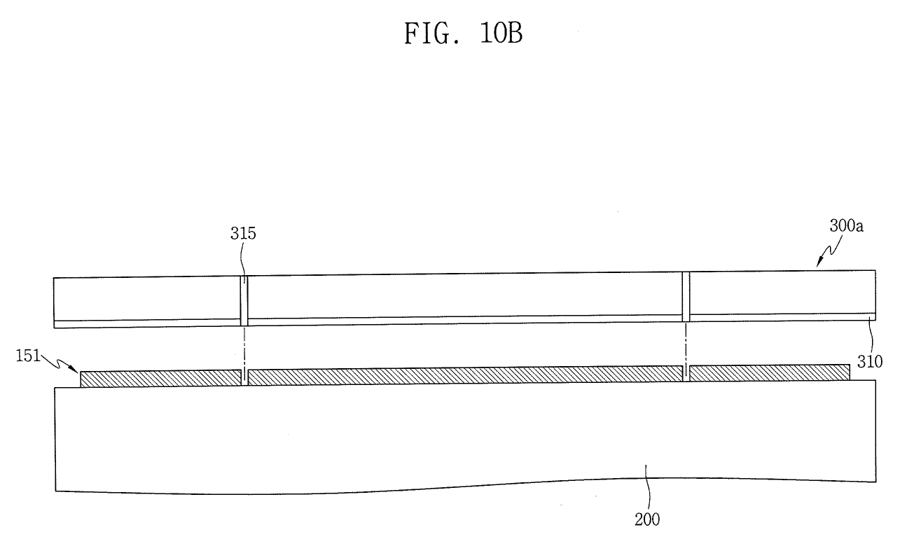

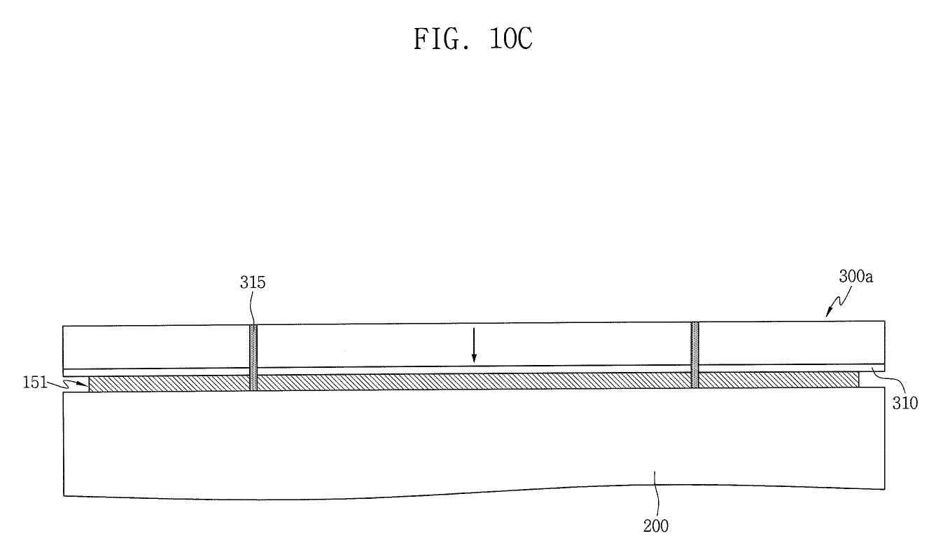

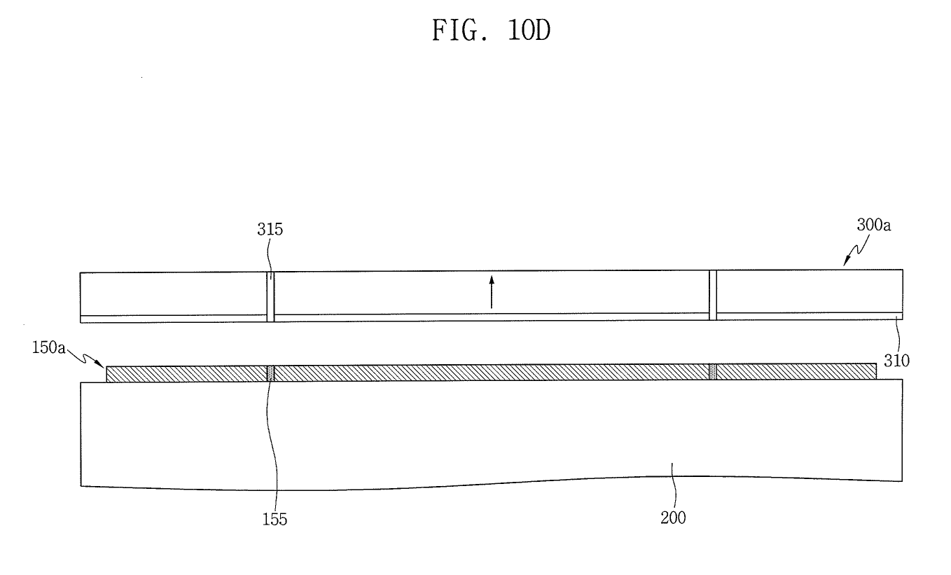

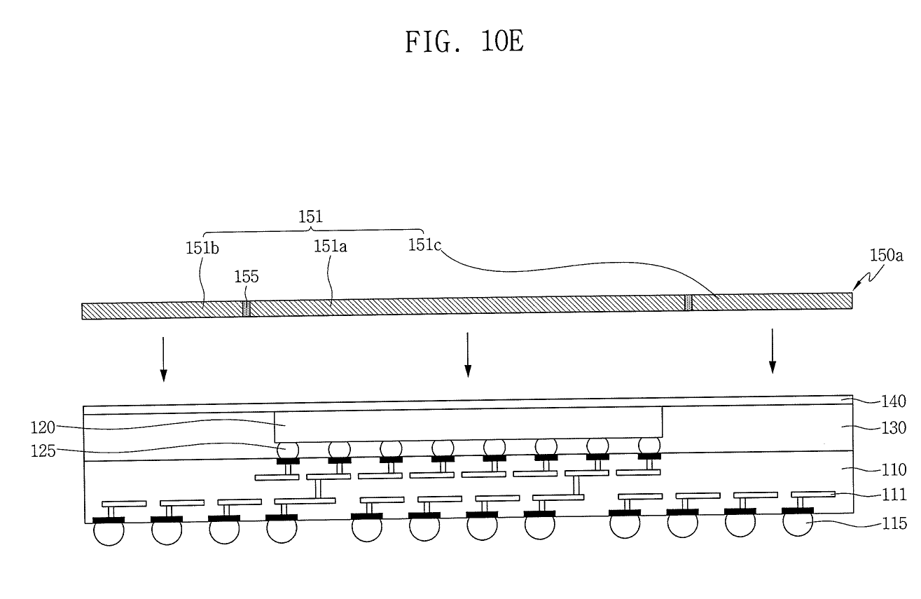

FIGS. 10A to 10E are diagrams for describing a method of manufacturing a semiconductor package according to an exemplary embodiment.

Referring to FIG. 1 OA, the method may include disposing a plurality of metal plates 151 on a support table 200. For example, the support table 200 may include a conveyer belt.

Referring to FIG. 10B, the method may include aligning the plurality of metal plates 151 below a mold device 300a. The mold device 300a may include nozzles 315 for discharging a bonding material. For example, the plurality of metal plates 151 may be disposed to be spaced apart from each other, and be aligned below the mold device 300a to locate the nozzles 315 in the spaced areas. A width of each of the nozzles 315 may be substantially equal to each of spaces between the plurality of metal plates 151. A lower surface of the mold device 300a may be planar. An area of the mold device 300a may be greater than a sum of areas of the metal plates 151. The mold device 300a may include a heat plate 310 in contact with the plurality of metal plates 151. The heat plate 310 may be provided on the lower surface of the mold device 300a. A lower surface of the heat plate 310 and an inlet of the nozzle 315 may have a substantially coplanar plane. When the alignment of the plurality of metal plates 151 and the mold device 300a is completed, the mold device 300a may be moved downward.

Referring to FIG. 10C, the method may include filling and curing a bonding material between the plurality of metal plates 151. For example, after aligning to locate the nozzles 315 between the plurality of metal plates 151, the method may include lowering the mold device 300a in a direction of an arrow, and disposing the mold device 300a on the upper surfaces of the plurality of metal plates 151. After this, the method may include filling the bonding material between the plurality of metal plates 151 using the nozzle 315, and curing the bonding material filled between the plurality of metal plates by heating the heat plate 310.

Referring to FIG. 10D, the method may include detaching the heat slug 150a including the plurality of metal plates 151 connected into one by the cured bonding material from the mold device 300a. In this case, the mold device 300a may be in a state raised in a direction of an arrow. By this method, the heat slug 150a in which the plurality of metal plates 151 are connected into one by the connection layer 155 may be manufactured.

Referring to FIG. 10E, the method may include bonding the heat slug 150a on the upper surface of the semiconductor package that a TIM is formed.

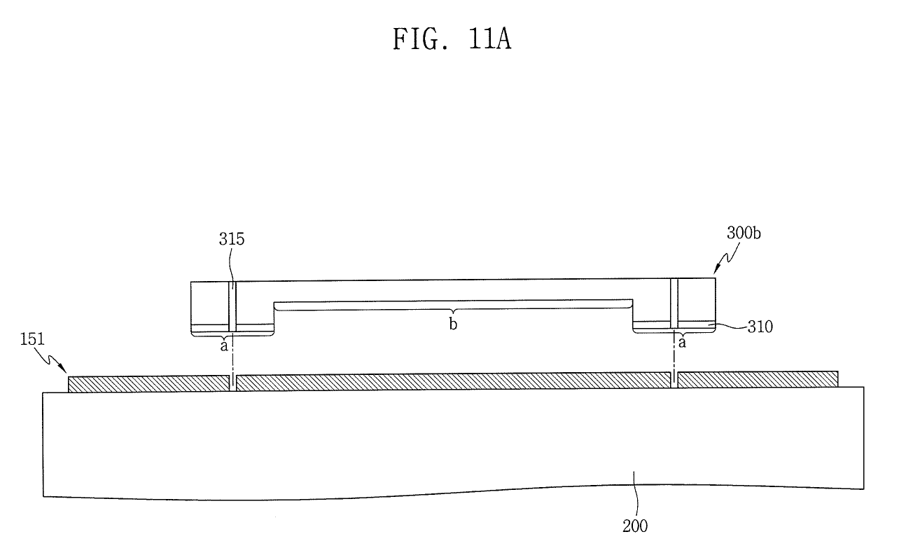

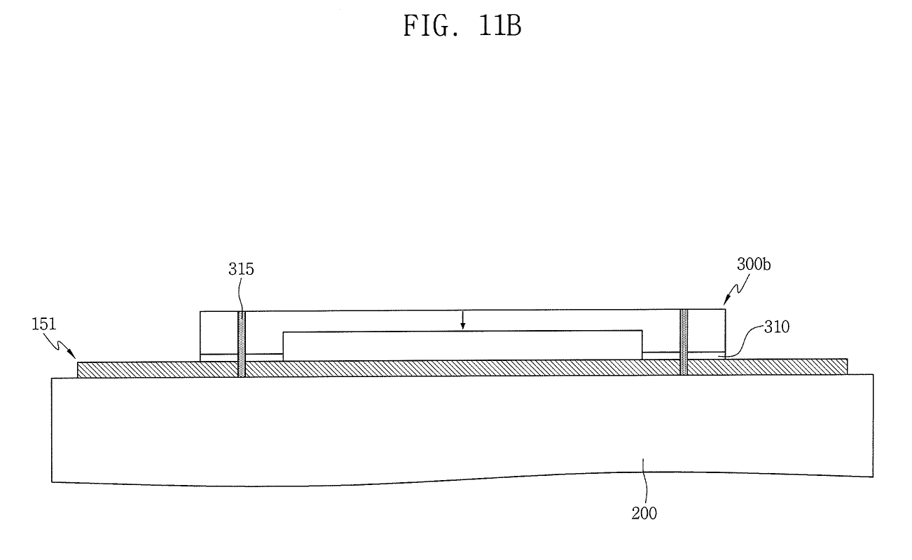

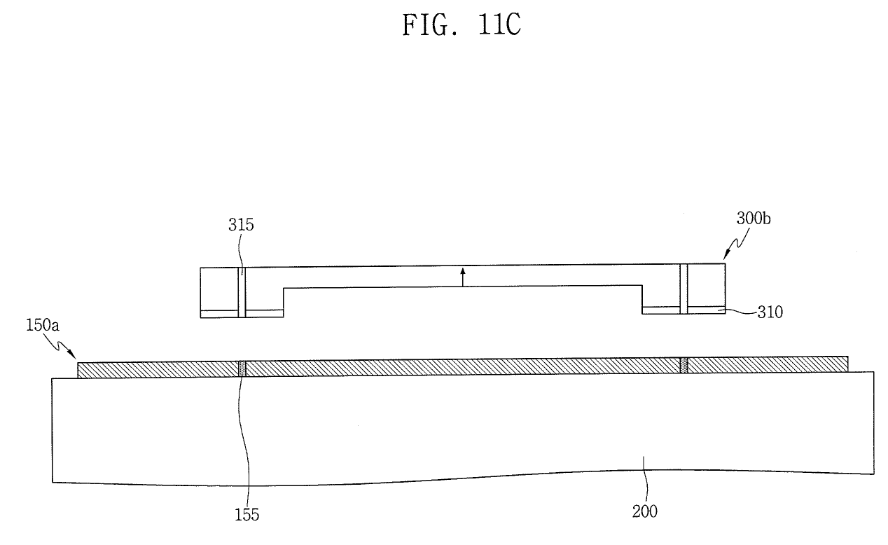

FIGS. 11A to 11C are diagrams for describing a method of manufacturing a semiconductor package according to an exemplary embodiment.

Referring to FIG. 10A, the method may include disposing a plurality of metal plates 151 on a support table 200. Next, referring to FIG. 11A, the method may include aligning the plurality of metal plates 151 below a mold device 300b.

The mold device 300b may include nozzles 315 for discharging a bonding material. A lower surface of the mold device 300b may be a stepped surface. For example, in the lower surface of the mold device 300b, first surfaces a in which the nozzles 315 are located in the mold device 300b may have different levels from a second surface b in which the nozzles 315 are not located. That is, the second surface b may have a concave shape formed between the first surfaces a. Accordingly, the first surfaces a in the lower surface of the mold device 300b may contact the upper surfaces of the metal plates 151, and the second surface b may not contact the upper surfaces of the metal plates 151. The first surfaces a may have greater widths than the nozzles 315. The mold device 300b may include heat plates 310 formed on lower surfaces of the first surfaces a. A lower surface of the heat plate 310 and an inlet of the nozzle 315 may have a substantially coplanar plane. An area of an upper surface of the mold device 300b may be smaller than a sum of areas of the plurality of metal plates 151.

Referring to FIG. 11B, the method may include filling and curing a bonding material between the plurality of metal plates 151.

Referring to FIG. 11C, the method may include detaching the heat slug 150a including the plurality of metal plates 151 connected into one by the bonding material from the mold device 300b. In this case, the mold device 300b may be in a state raised in direction of an arrow.

Referring back to FIG. 10E, the method may include bonding the heat slug 150a on the upper surface of the semiconductor package on that a TIM is formed.

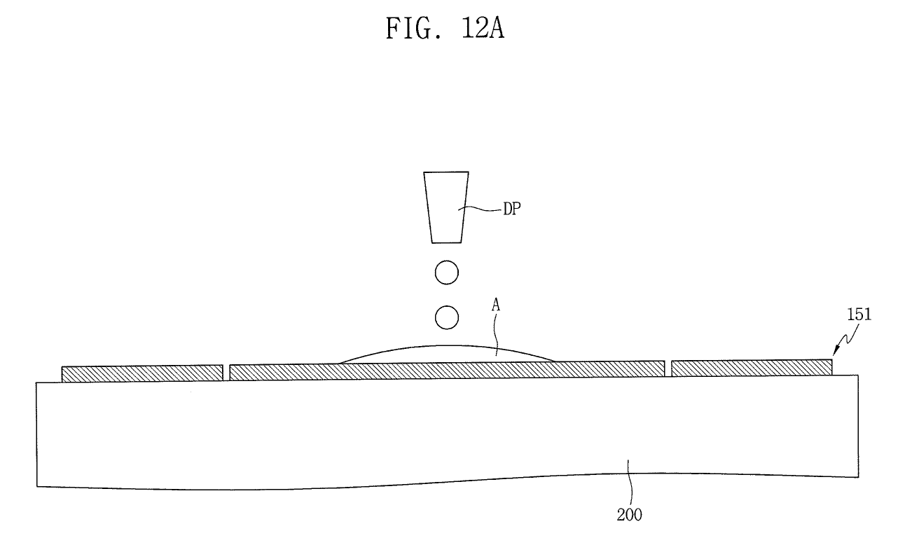

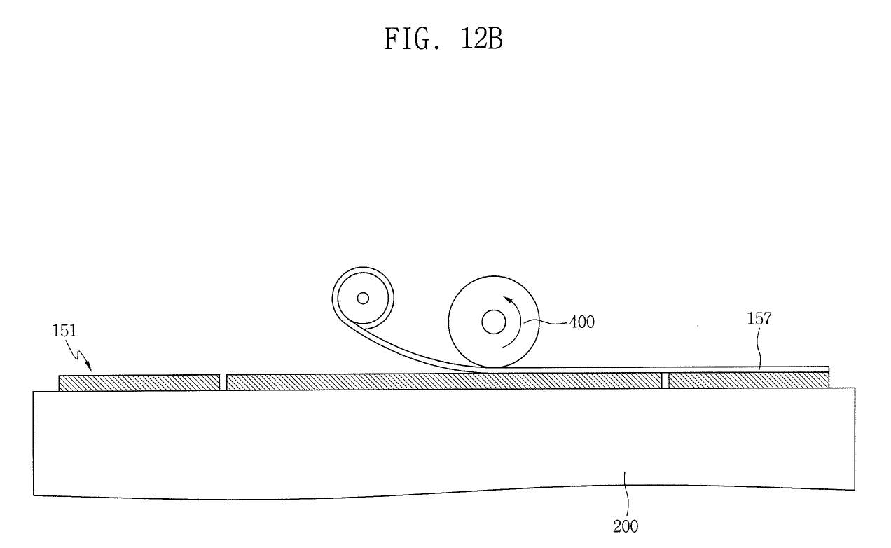

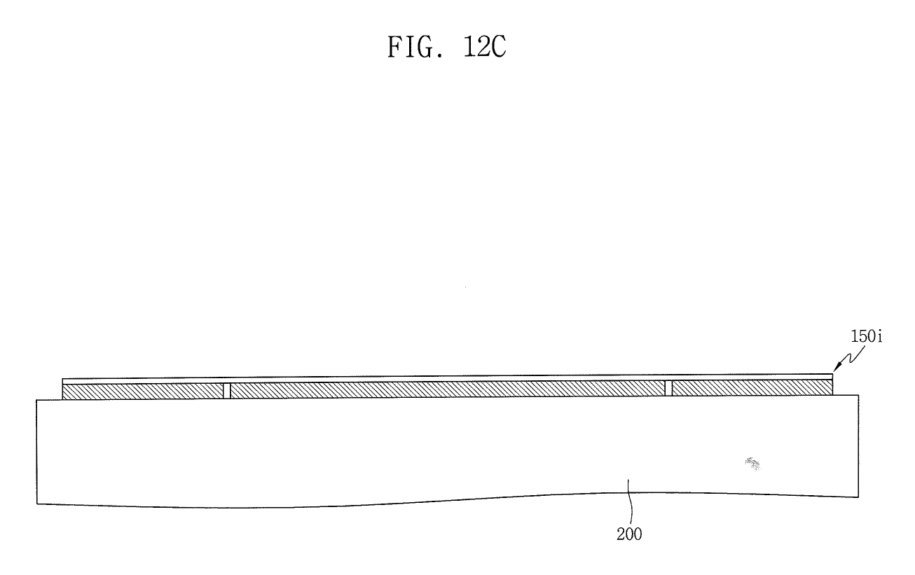

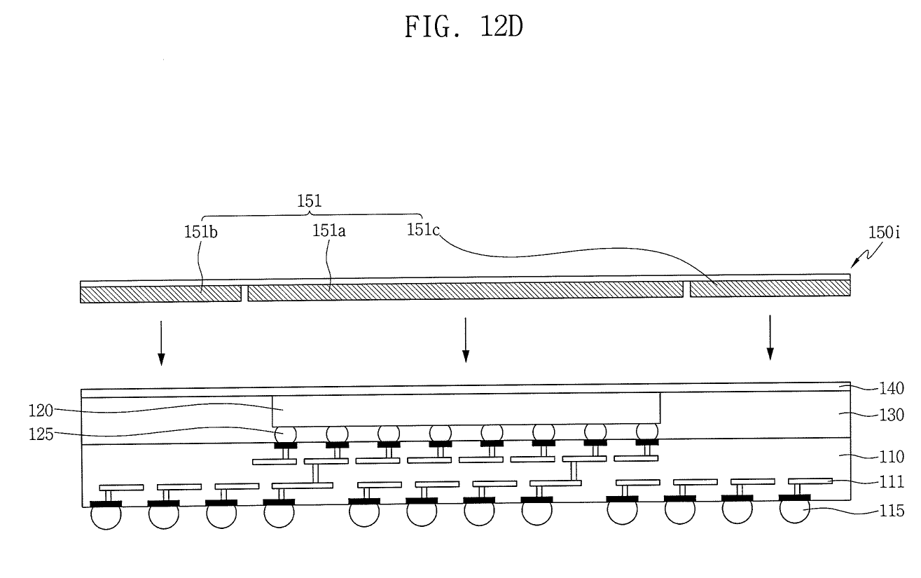

FIGS. 12A to 12D are diagrams for describing a method of manufacturing a semiconductor package according to an exemplary embodiment.

Referring to FIG. 10A, the method may include disposing a plurality of metal plates 151 on a support table 200. Next, referring to FIG. 12A, the method may include coating a bonding material A on upper surfaces of the plurality of metal plates 151.

The bonding material A may be coated on the upper surfaces of the metal plates 151 using a dispenser DP including a nozzle. The bonding material A may include a TIM, or a bonding material in which a filler and a resin are mixed. For example, the bonding material A coated on the upper surface of the metal plates 151 may be formed to have a uniform thickness using a roller, etc.

Referring to FIGS. 12B and 12C, the method may include bonding a capping film 157 on the upper surfaces of the plurality of metal plates 151. For example, the capping film 157 on the upper surfaces of the metal plates 151 is stacked, and the capping film 157 stacked on the upper surfaces of the metal plates 151 is pressed with a heated roller 400 at the same time, and thus the bonding material A may be cured and the capping film 157 on the upper surfaces of the metal plates 151 may be bonded. The capping film 157 may include a polyimide film, or a metal film. The metal film may include one of copper (Cu), gold (Au), aluminum (Al), nickel (Ni), or an alloy thereof. The heat slug 150i according to the embodiment may be manufactured by processing the plurality of metal plates 151 connected into one by the capping film 157 as a required size if necessary.

Referring to FIG. 12D, the method may include bonding the heat slug 150i on the upper surface of the semiconductor package that a TIM is formed.

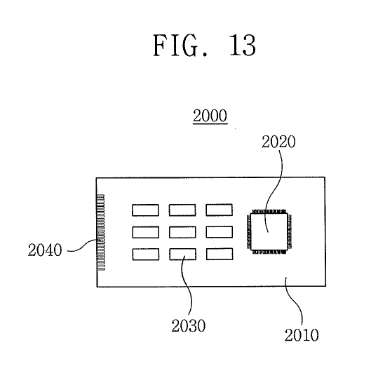

FIG. 13 is a schematic diagram illustrating a module according to an embodiment including the semiconductor packages according to various exemplary embodiments. Referring to FIG. 13, a module 2000 according to the embodiment may include a semiconductor device 2030 mounted on a module substrate 2010, and the semiconductor device 2030 may include the semiconductor package structures according to the various exemplary embodiments. The module 2000 may further include a microprocessor 2020 mounted on the module substrate 2010. Input and output terminals 2040 may be disposed on at least one side of the module substrate 2010. The semiconductor device 2030 may be mounted on the module substrate 2010 using a flip-chip technique, etc.

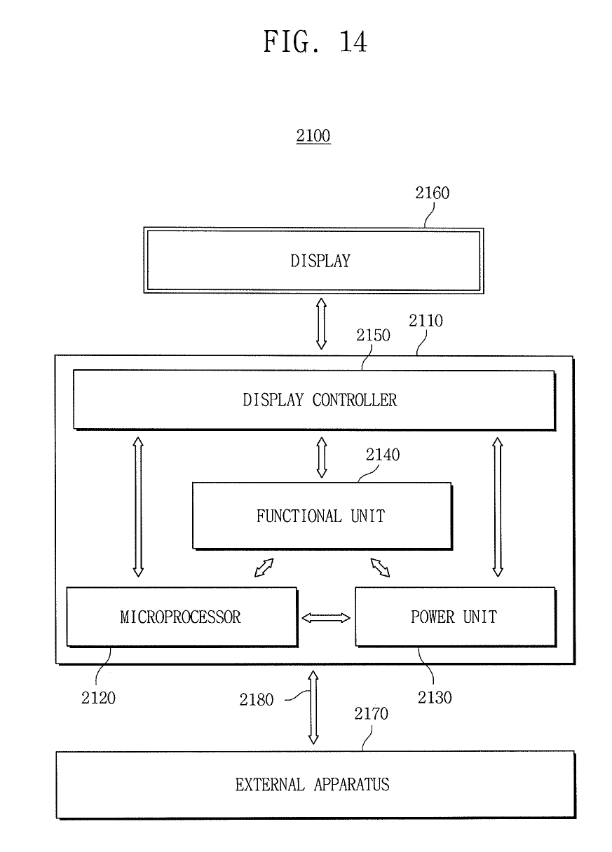

FIG. 14 is a schematic diagram illustrating an electronic system according to another embodiment.

Referring to FIG. 14, the semiconductor packages according to the various exemplary embodiments may be applied to an electronic system 2100. The electronic system 2100 may include a body 2110, a microprocessor 2120, a power unit 2130, a functional unit 2140, and a display controller 2150. The body 2110 may be a motherboard formed by a printed circuit board (PCB). The microprocessor 2120, the power unit 2130, the functional unit 2140, and the display controller 2150 may be mounted on the body 2110. A display unit 2160 may be disposed on the inside or outside of the body 2110. For example, the display unit 2160 may be disposed on a surface of the body 2110, and display an image processed by the display controller 2150.

The power unit 2130 may receive a predetermined voltage from an external battery (not shown), etc., divide the predetermined voltage into required voltage levels, and supply the required voltage levels to the microprocessor 2120, the functional unit 2140, the display controller 2150, etc. The microprocessor 2120 may receive the required voltage level from the power unit 2130, and control the functional unit 2140 and the display unit 2160. The functional unit 2140 may perform various functions of the electronic system 2100. For example, when the electronic system 2100 is a mobile phone, the functional unit 2140 may include several elements capable of performing functions of the mobile phone, such as output of an image to the display unit 2160 or output of a voice to a speaker, by dialing or communication with an external apparatus 2170, and when including a camera together, the functional unit 2140 may serve as a camera image processor.

In applicable embodiment, when the electronic system 2100 is connected to a memory card, etc. to increase capacity, the functional unit 2140 may be a memory card controller. The functional unit 2140 may transmit and receive signals to/from the external apparatus 2170 through a wired or wireless communication unit 2180. In addition, when the electronic system 2100 needs a Universal Serial Bus (USB) to expand functions thereof, the functional unit 2140 may serve as an interface controller. Further, the functional unit 2140 may include a mass storage device.

The semiconductor packages according to the various embodiments may be applied to the functional unit 2140 or the microprocessor 2120. For example, the microprocessor 2120 may include the heat slug including the plurality of metal plates 151 spaced apart by a predetermined distance from each other. The microprocessor 2120 may improve a bonding strength between the heat slug and the semiconductor package and then have excellent heat dissipation characteristics by preventing delamination between the heat slug and the TIM formed on the upper surface of semiconductor package compared with the conventional art due to a structure of the heat slug.

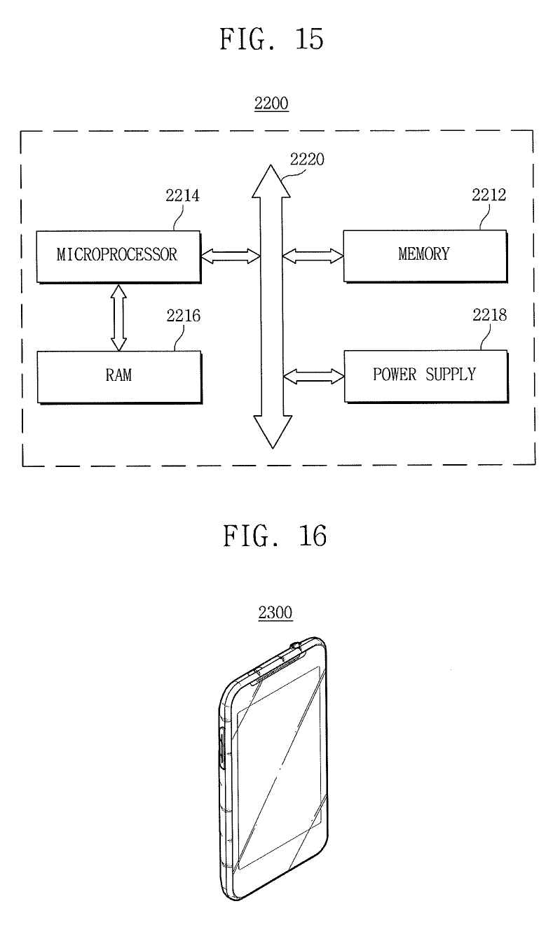

FIG. 15 is a schematic diagram illustrating another electronic system including at least one among the semiconductor packages according to various exemplary embodiments.

Referring to FIG. 15, an electronic system 2200 may include at least one among the semiconductor packages according to various embodiments. The electronic system 2200 may be used for manufacturing a mobile device or a computer. For example, the electronic system 2200 may include a memory 2212, a microprocessor 2214, a random access memory (RAM) 2216, and a power supply 2218. The microprocessor 2214 may program and control the electronic system 2200. The RAM 2216 may be used as an operational memory of the microprocessor 2214. The microprocessor 2214, the RAM 2216, and/or other elements may be assembled within a single package. The memory 2212 may store operational codes of the microprocessor 2214, data processed by the microprocessor 2214, or external input data. The memory 2212 may include a controller and a memory.

The semiconductor packages according to various embodiments may be applied to the microprocessor 2214, the RAM 2216, or the memory 2212. For example, the microprocessor 2214 may include the heat slug including the plurality of metal plates 151 disposed to be spaced apart by a predetermined distance from each other. The microprocessor 2214 may improve a bonding strength between the heat slug and the semiconductor package and then have excellent heat dissipation characteristics by preventing delamination between the heat slug and the TIM formed on the upper surface of semiconductor package compared with the conventional art due to a structure of the heat slug.

FIG. 16 is a schematic diagram illustrating a mobile wireless phone 2300 including at least one among the semiconductor packages according to various embodiments. The mobile wireless phone 2300 may be understood as a tablet personal computer (PC). In addition, at least one among the semiconductor packages according to the various exemplary embodiments may be applied to a portable computer such as a notebook, a MPEG-1 audio layer 3 (MP3) player, a MP4 player, a navigation device, a solid state disk (SSD), a table computer, an automobile, and home appliances, in addition to the tablet PC.

In addition, names and functions of elements that the reference numerals are not shown or only reference numerals are shown in figures or drawings may be understood easily from other figures or description thereof of the present specification.

The heat slug according to various exemplary embodiments may actively respond to a direction of warpage of a semiconductor package since a plurality of metal plates are spaced apart from each other.

The semiconductor packages according to various exemplary embodiments may actively respond to the direction of warpage of the semiconductor package generated during a manufacturing process by including the heat slug having a plurality of metal plates spaced apart from each other, and then a bonding strength between a TIM of an upper surface of the semiconductor package and the heat slug can be improved. Accordingly, the semiconductor packages can have structural stability, and also effectively dissipate heat generated from the semiconductor chip.

The foregoing is illustrative of embodiments and is not to be construed as limiting thereof. Although a few embodiments have been described, those skilled in the art will readily appreciate that many modifications are possible without materially departing from the novel teachings and advantages. Accordingly, all such modifications are intended to be included within the scope of this inventive concept as defined in the claims. In the claims, means-plus-function clauses are intended to cover the structures described herein as performing the recited function, and not only structural equivalents but also equivalent structures.

What is claimed is:

1. A semiconductor package, comprising:
a substrate;
a semiconductor chip mounted on an upper surface of the substrate;
an encapsulant covering sides of the semiconductor chip on the upper surface of the substrate;
a heat transfer layer on an upper surface of the semiconductor chip and an upper surface of the encapsulant; and
a heat slug on an upper surface of the heat transfer layer, the heat slug including a plurality of metal plates disposed to be spaced apart from each other on the upper surface of the heat transfer layer.

2. The semiconductor package according to claim 1, wherein the heat slug further comprises a connection layer between the plurality of metal plates.

3. The semiconductor package according to claim 2, wherein the connection layer comprises a bonding material including a filler and a resin, or a thermal interface material (TIM).

4. The semiconductor package according to claim 2, wherein the plurality of metal plates are coplanar with the connection layer.

5. The semiconductor package according to claim 2, wherein the connection layer has a plurality of shapes parallel to each other in a plan view.

6. The semiconductor package according to claim 1, wherein the heat slug further comprises a capping film on the plurality of metal plates.

7. The semiconductor package according to claim 6, wherein the capping film comprises a polyimide film, or a metal film.

8. The semiconductor package according to claim 7, wherein the metal film comprises one of copper (Cu), gold (Au), aluminum (Al), nickel (Ni), or an alloy thereof.

9. The semiconductor package according to claim 6, wherein an air space exists between the heat transfer layer and the capping film.

10. The semiconductor package according to claim 1, wherein the heat transfer layer is interposed between the plurality of metal plates.

11. The semiconductor package according to claim 1, wherein the heat transfer layer comprises a thermal interface material (TIM), or a thermally conductive filler.

12. The semiconductor package according to claim 1, wherein the plurality of metal plates comprise one of copper (Cu), gold (Au), aluminum (Al), nickel (Ni), or an alloy thereof.

13. The semiconductor package according to claim 1, wherein the encapsulant covers the upper surface of the semiconductor chip.

14. The semiconductor package according to claim 1, wherein the plurality of metal plates comprise a first metal plate located on the upper surface of the semiconductor chip and a second metal plate located on the encapsulant, and the first metal plate has a greater horizontal width than the second metal plate.

15. A semiconductor package, comprising:
a semiconductor chip mounted on a substrate;
an encapsulant covering sides of the semiconductor chip;
a plurality of metal plates disposed on the semiconductor chip and the encapsulant; and
a connection layer disposed between the plurality of metal plates,
wherein the plurality of metal plates includes:
a first metal plate disposed on the semiconductor chip, and
a second metal plate and a third metal plate disposed on the encapsulant at two sides of the first metal plate.

16. The semiconductor package according to claim 15, further comprising a heat transfer layer interposed between the plurality of metal plates and the semiconductor chip, and between the plurality of metal plates and the encapsulant.

17. The semiconductor package according to claim 15, wherein the connection layer comprises a bonding material including a filler and a resin, or a thermal interface material (TIM).

18. The semiconductor package according to claim 15, wherein the first metal plate has substantially a greater thickness than the second and third metal plates.

19. A semiconductor package, comprising:
a substrate;
a semiconductor chip mounted on an upper surface of the substrate;
an encapsulant covering sides of the semiconductor chip on the upper surface of the substrate;
a heat transfer layer on an upper surface of the semiconductor chip and an upper surface of the encapsulant; and
a heat slug on an upper surface of the heat transfer layer,
wherein the heat slug includes a plurality of metal plates disposed to be spaced apart from each other on the upper surface of the heat transfer layer, and a connection layer disposed between the plurality of metal plates.

20. The semiconductor package according to claim 19, wherein the heat slug further comprises a capping film on the plurality of metal plates.
